(19) United States
(12) Patent Application Publication
(10) Pub. No.: US 2007/0210406 A1
(43) Pub. Date: Sep. 13, 2007

(54) Semiconductor device and method of manufacturing the same

(76) Inventors: Jun Hirota, Yokohama-shi (JP); Hideo Shinomiya, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/715,963

(22) Filed: Mar. 9, 2007

(30) Foreign Application Priority Data
Mar. 10, 2006 (JP) 2006-065933

(51) Int. Cl. H01L 29/00; H01L 21/44

(52) U.S. Cl. 257/499; 438/597

(57) ABSTRACT

A semiconductor device includes a first interlayer insulating film, a second interlayer insulating film formed on the first interlayer insulating film, a plug having a lower portion surrounded by the first interlayer insulating film and an upper portion projecting from the first interlayer insulating film and surrounded by the second interlayer insulating film, a wire formed in the second interlayer insulating film, and having a connected portion that is connected to the plug and a non-connected portion that is not connected to the plug, and a stopper insulating film formed in a region between the first interlayer insulating film and the non-connected portion of the wire and between the second interlayer insulating film and the upper portion of the plug.

### CROSS-REFERENCE TO RELATED APPLICATIONS

This application is based upon and claims the benefit of priority from prior Japanese Patent Application No. 2006-065933, filed Mar. 10, 2006, the entire contents of which are incorporated herein by reference.

### BACKGROUND OF THE INVENTION

1. Field of the Invention

The present invention relates to a semiconductor device and a method of manufacturing the same.

2. Description of the Related Art

In recent years, there has been a growing demand for an increase in integration density and operation speed in semiconductor devices. For this purpose, so-called damascene wiring has been widely proposed (see Jpn. Pat. Appln. KOKAI Publication No. 11-307630).

FIG. 6 is a schematic cross-sectional view showing a configuration of a conventional semiconductor device. The semiconductor device has an interlayer insulating film 51, a plug 52, a stopper insulating film 53, an interlayer insulating film 54, a copper wire 55 and a diffusion preventing film 56.

In the conventional semiconductor device shown in FIG. 6, the stopper insulating film is formed in the overall region between the adjacent copper wires 55. Therefore, a leakage current path is formed in an interface between the stopper insulating film 53 and the interlayer insulating film 51 and an interface between the stopper insulating film 53 and the interlayer insulating film 54. This is a considerable factor of leakage between wires. Further, since a silicon nitride film having a high dielectric constant is generally used as the stopper insulating film 53, the capacitance between wires increases. This is a considerable factor of reduction in operation speed.

Further, in the conventional semiconductor device shown in FIG. 6, when a trench for the copper wire 55 is formed by etching, the etching cannot be completely stopped by the stopper insulating film 53, and the interlayer insulating film 51 is also etched. Therefore, corner portions of the plugs 52 enter the copper wires 55, as shown in FIG. 6. As a result, the electromigration lifetime deteriorates.

As described above, the conventional semiconductor device has problems caused by the stopper insulating film. Consequently, according to the conventional art, it was difficult to produce a semiconductor device having excellent properties and high reliability.

### BRIEF SUMMARY OF THE INVENTION

According to a first aspect of the present invention, there is provided a semiconductor device comprising: a first interlayer insulating film; a second interlayer insulating film formed on the first interlayer insulating film; a plug having a lower portion surrounded by the first interlayer insulating film and an upper portion projecting from the first interlayer insulating film and surrounded by the second interlayer insulating film; a wire formed in the second interlayer insulating film, and having a connected portion that is connected to the plug and a non-connected portion that is not connected to the plug; and a stopper insulating film formed in a region between the first interlayer insulating film and the non-connected portion of the wire and between the second interlayer insulating film and the upper portion of the plug.

According to a second aspect of the present invention, there is provided a method of manufacturing a semiconductor device, comprising: forming a stopper insulating film on a first interlayer insulating film; forming a connection hole in the first interlayer insulating film and the stopper insulating film; forming a plug material film on the stopper insulating film and in the connection hole; removing that part of the plug material film which is formed on the stopper insulating film using the stopper insulating film as a stopper, thereby forming a plug in the connection hole; forming a mask portion on the stopper insulating film and the plug; etching the stopper insulating film using the mask portion as a mask, thereby exposing an upper surface of the first interlayer insulating film; forming a second interlayer insulating film surrounding the mask portion on the first interlayer insulating film; removing the mask portion to form a trench for wiring; and forming a wire connected to the plug in the trench.

### BRIEF DESCRIPTION OF THE SEVERAL VIEWS OF THE DRAWING

FIGS. 1 to 5 are schematic cross-sectional views showing steps for manufacturing a semiconductor device according to an embodiment of the present invention; and

FIG. 6 is a schematic cross-sectional view showing a configuration of a semiconductor device according to prior art.

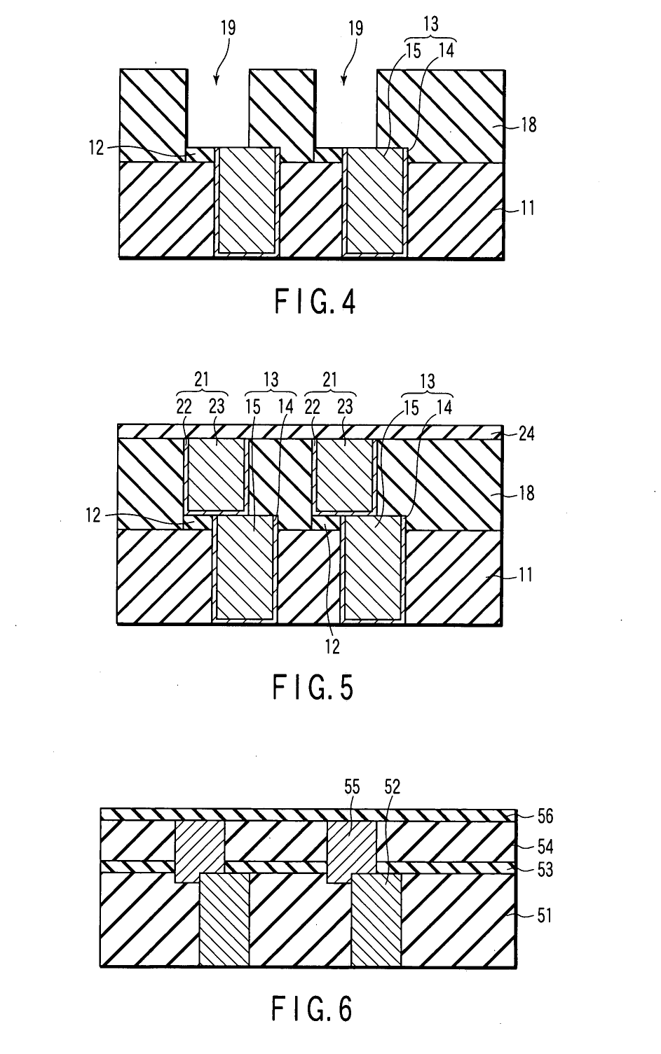

### DETAILED DESCRIPTION OF THE INVENTION

An embodiment of the present invention will be described below with reference to the accompanying drawings.

FIG. 5 is a schematic cross-sectional view showing a configuration of a semiconductor device according to an embodiment of the present invention. The configuration of the semiconductor device of the embodiment will be described with reference to FIG. 5.

An interlayer insulating film (first interlayer insulating film) 11 made of a silicon oxide film is provided on an underlying region (not shown) including a semiconductor substrate and transistors. A plug 13 is formed in the interlayer insulating film 11. The plug 13 includes a barrier metal film (liner metal film) 14 formed on the side wall of a connection hole, and a metal film 15, such as a tungsten film (W film), formed on the barrier metal film 14. The plug 13 has a lower portion surrounded by the interlayer insulating film 11, and an upper portion projecting from the interlayer insulating film 11 and surrounded by the interlayer insulating film (second interlayer insulating film) 18 formed on the interlayer insulating film 11.

The interlayer insulating film 18 is formed of a silicon oxide film. A wire 21 surrounded by the interlayer insulating film 18 is formed in the interlayer insulating film 18. The wire 21 has a barrier film 22 formed on the side walls of a wiring trench, and a copper film (Cu film) 23 formed on the barrier film 22. The semiconductor device is designed such that the width of the wire 21 is equal to that of the plug 13, and that the side surfaces of the wire 21 align with the side surfaces of the plug 13. In general, however, the wire 21 and the plug 13 misalign with each other. Therefore, the wire 21 has a connected portion that is connected to the plug 13 and a non-connected portion that is not connected to the plug 13.

A stopper insulating film 12 formed of a silicon nitride film is provided in a region just under the non-connected portion of the wire 21. More specifically, the stopper insulating film 12 is formed in the region between the interlayer insulating film 11 and the non-connected portion of the wire 21 and between the interlayer insulating film 18 and the upper portion of the plug 13. When the plug 13 is formed by CMP (chemical mechanical polishing), the stopper insulating film 12 serves as a CMP stopper. Therefore, the upper surface of the plug 13 is flush with the upper surface of the stopper insulating film 12. In other words, the upper portion of the plug 13 has a height, which is equal to a thickness of the stopper insulating film 12. A diffusion preventing film 24 is formed on the interlayer insulating film 18 and the wire 21.

As described above, the stopper insulating film 12 is formed only in the region just under the wire 21. If the stopper insulating film 12 were formed in the overall region between the upper portions of the plugs, a leakage current path might be formed in an interface between the stopper insulating film 12 and the interlayer insulating film 11 and an interface between the stopper insulating film 12 and the interlayer insulating film 18. The leakage current path may be a considerable factor of leakage between wires. In this embodiment, since the stopper insulating film 12 is formed only in the region just under the wire 21, a leakage current path will not be formed and leakage between wires can be reduced.

Moreover, the stopper insulating film 12 is formed of a silicon nitride film. The silicon nitride film has a higher dielectric constant than the silicon oxide film used for the interlayer insulating films 11 and 18. Therefore, if the stopper insulating film 12 were formed in the overall region between the upper portions of the plugs, the capacitance between the wires would increase, resulting in reduction in operation speed. In this embodiment, since the stopper insulating film 12 is formed only in the region just under the wire 21, the capacitance between the wires can be reduced. Therefore, the operation speed can be increased.

Further, the upper surface of the plug 13 is flush with the upper surface of the stopper insulating film 12. Therefore, the plug 13 and the wire 21 are in contact with each other only at the upper surface of the plug 13 and the lower surface of the wire 21. In other words, corner portions of the plug 13 do not enter the wire 21. Consequently, the electromigration lifetime is improved, thereby preventing reduction in reliability of the wiring.

As described above, the semiconductor device of this embodiment can prevent problems caused by the stopper insulating film 12, such as the increase in leakage between wires and the increase in capacitance between wires. Further, the semiconductor device of this embodiment can improve the electromigration lifetime. Thus, according to the above embodiment, a semiconductor device having excellent properties and high reliability can be attained.

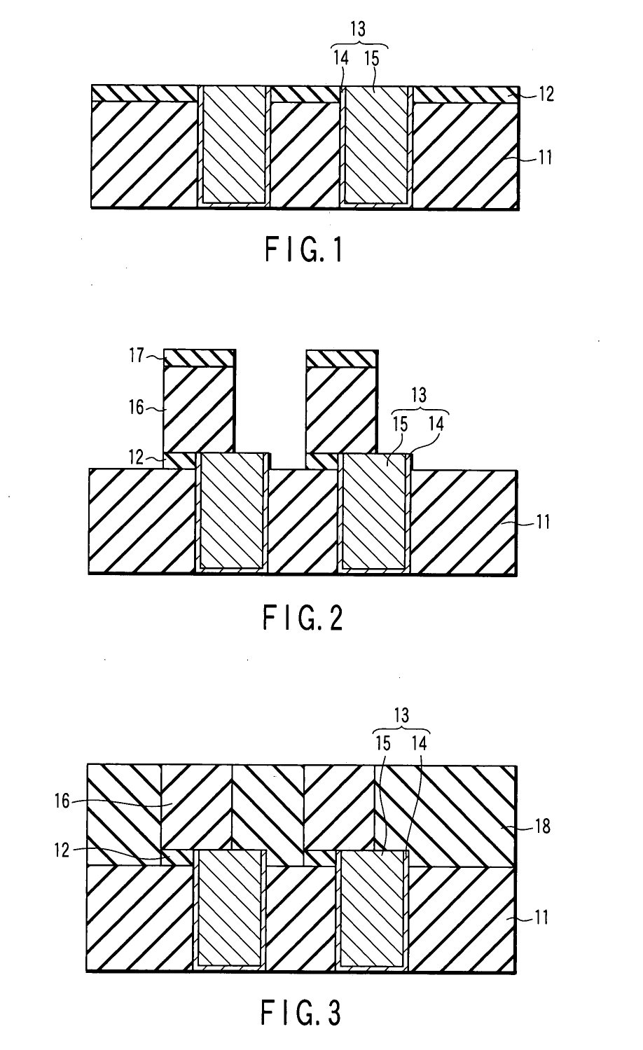

A method for manufacturing a semiconductor device according to the embodiment will now be described with reference to FIGS. 1 to 5. FIGS. 1 to 5 are schematic cross-sectional views showing steps for manufacturing a semiconductor device according to the embodiment of the present invention.

First, as shown in FIG. 1, the interlayer insulating film (first interlayer insulating film) 11 is formed on an underlying region (not shown) including the semiconductor substrate and transistors. The interlayer insulating film 11 is formed of a silicon oxide film produced by plasma CVD (chemical vapor deposition) using silane (SiH₄) as a source gas. Then, a silicon nitride film having a thickness of about 35 nm, as the stopper insulating film 12, is formed on the interlayer insulating film 11 by plasma CVD. The F stopper insulating film 12 is not limited to a silicon nitride film, but may be an SiC film, an SiCN film, an SiOC film, an SiCH film, an SiON film or the like.

Thereafter, a photoresist pattern (not shown) having an opening is formed on the stopper insulating film 12 by photolithography. Using the photoresist pattern as a mask, the interlayer insulating film 11 and the stopper insulating film 12 are etched by RIE (reactive ion etching). For example, CHF₃ may be used as an etching gas. As a result, a connection hole (for example, a via hole) is formed in the interlayer insulating film 11 and the stopper insulating film 12. Then, the photoresist pattern is removed by ashing. The ashing is performed in an atmosphere of oxygen at a pressure of about 0.1 Pa to 500 Pa and a temperature of about 200° C. to 400° C. Further, residues (which have been produced by etching and ashing) adhering to the inner surfaces of the connection hole are removed by an organic or inorganic chemical solution.

Then, a plug material film 13 is formed on the stopper insulating film 12 and in the connection hole. Specifically, as a first step, the barrier metal film (liner metal film) 14 is formed on the overall surface by sputtering. A titanium film (Ti film) or a stack film of a titanium film (Ti film) and a titanium nitride film (TiN film) may be used as the barrier metal film 14. Secondly, a tungsten film (W film) is formed as the metal film 15 on the barrier metal 14 by CVD. As a result, the plug material film 13 composed of the barrier metal film 14 and the metal film 15 is obtained.

Thereafter, using the stopper insulating film 12 as a stopper, the plug material film 13 (the barrier metal film 14 and the metal film 15) formed on the stopper insulating film 12 is removed by CMP (chemical mechanical polishing). As a result, a plug made of the plug material film 13 is formed in the connection hole. In this process, CMP is performed such that the height of the plug 13 becomes equal to that of the stopper insulating film 12. In other words, CMP is performed such that the upper surface of the plug 13 is flush with the upper surface of the stopper insulating film 12.

Then, as shown in FIG. 2, a mask material film 16 is formed on the overall surface of the stopper insulating film 12 and the plug 13 by coating. Organic polyphenylene can be used as the mask material film 16. The coated mask material film 16 is subjected to a heat process at a temperature of about 100° C. to 400° C. Thereafter, a hard mask film 17 is formed on the mask material film 16. A silicon oxide film using D-TEOS is used as the hard mask film 17. Further, a photoresist pattern (not shown) is formed on the hard mask film 17 by photolithography.

Using the photoresist pattern as a mask, the hard mask film 17 is etched, thereby forming a hard mask pattern. CHF₃ or the like is used as the etching gas. Then, the mask material film 16 is etched using the hard mask pattern 17 as a mask, thereby forming a mask portion. A mixture of O₂ and CH₄ or a mixture of N₂ and H₂ is used as the etching gas. Further, using the hard mask pattern 17 and the mask portion 16 as a mask, the stopper insulating film 12 is etched by CF₄ gas. In this process, the stopper insulating film 12 is selectively etched relative to the plug 13 and the interlayer insulating film 11. As a result of the etching, the upper surface of the interlayer insulating film 11 is exposed, and a part of the stopper insulating film 12 remains in a region just under the mask portion 16. Then, the hard mask pattern 17 is removed. Further, residues (which have been produced by etching) adhering to the surfaces of the stopper insulating film 12, the plug 13 and the mask portion 16 are removed by an organic or inorganic chemical solution.

Then, as shown in FIG. 3, the interlayer insulating film (second interlayer insulating film) 18 is formed on the overall surface. A silicon oxide film using D-TEOS is used as the interlayer insulating film 18. Subsequently, the interlayer insulating film 18 is flattened by CMP. In this time, CMP is performed such that the height of the interlayer insulating film 18 becomes equal to that of the mask portion 16. As a result, the mask portion 16 is surrounded by the interlayer insulating film 18.

Next, as shown in FIG. 4, a trench 19 for wiring is formed by removing the mask portion 16. In this time, the mask portion 16 is selectively etched relative to the stopper insulating film 12, the plug 13 and the interlayer insulating film 18. In the case where organic polyphenylene is used as the mask portion 16, the mask portion 16 can be selectively etched by ashing. The ashing is performed in an atmosphere of oxygen at a pressure of about 0.1 Pa to 500 Pa and a temperature of about 200° C. to 400° C. Further, residues (which have been produced by ashing) adhering to the inner surface of the trench 19 and a native oxide film formed on the surface of the plug 13 are removed by an organic or inorganic chemical solution.

Then, as shown in FIG. 5, a wire material film 21 is formed on the interlayer insulating film 18 and in the trench 19 for wiring. More specifically, first, the barrier film 22 is formed. The purpose of the barrier film 22 is to prevent copper contained in the copper film (Cu film) from diffusing. A tantalum film (Ta film), a titanium film (Ti film), a Ta alloy film, a Ti alloy film or the like can be used as the barrier film 22. Then, a Cu seed layer is formed on the barrier film 22. Thereafter, the copper film (Cu film) 23 is formed on the Cu seed layer by electroplating. Alternatively, the copper film 23 may be formed by electroless plating. Further, annealing is performed at a temperature of about 300° C. Thus, the wire material film 21 made of the barrier film 22 and the copper film 23 is obtained. The wire material film 21 is flattened by CMP. Consequently, the wire 21 connected to the plug 13 is formed in the trench 19.

Thereafter, the diffusion preventing film 24, which prevents copper diffusion, is formed on the interlayer insulating film 18 and the wire 21. An SiN film, an SiCN film, an SiC film, an SiOC film, an SiON film or the like may be used as the diffusion preventing film 24. Thus, a wiring structure having a single damascene structure as shown in FIG. 5 is obtained.

As has been described above, according to the manufacturing method of the above embodiment, after the stopper insulating film 12 is formed, the connection hole is formed in the interlayer insulating film 11 and the stopper insulating film 12, and the plug 13 is formed in the connection hole. Then, the stopper insulating film 12 is etched by using the mask portion 16 as a mask. Therefore, it is ensured that the stopper insulating film 12 is formed only in the region just under the wire 21. As a result, the leakage between wires and the capacitance between wires, caused by the stopper insulating film 12, can be reduced. Consequently, it is ensured that a semiconductor device having excellent properties and high reliability is produced. Further, since the upper surface of the plug 13 is flush with the upper surface of the stopper insulating film 12, the corner portion of the plug 13 do not enter the wire 21. As a result, a semiconductor device having improved electromigration lifetime can be surely produced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first interlayer insulating film;
a second interlayer insulating film formed on the first interlayer insulating film;
a plug having a lower portion surrounded by the first interlayer insulating film and an upper portion projecting from the first interlayer insulating film and surrounded by the second interlayer insulating film;
a wire formed in the second interlayer insulating film, and having a connected portion that is connected to the plug and a non-connected portion that is not connected to the plug; and
a stopper insulating film formed in a region between the first interlayer insulating film and the non-connected portion of the wire and between the second interlayer insulating film and the upper portion of the plug.

2. The semiconductor device according to claim 1, wherein an upper surface of the plug is flush with an upper surface of the stopper insulating film.

3. The semiconductor device according to claim 1, wherein the second interlayer insulating film has a dielectric constant, which is lower than that of the stopper insulating film.

4. The semiconductor device according to claim 1, wherein the wire has a width, which is equal to that of the plug.

5. The semiconductor device according to claim 1, wherein the first interlayer insulating film is formed of a silicon oxide film.

6. The semiconductor device according to claim 1, wherein the second interlayer insulating film is formed of a silicon oxide film.

7. The semiconductor device according to claim 1, wherein the stopper insulating film is formed of a silicon nitride film, an SiC film, an SiCN film, an SiOC film, an SiCH film or an SiON film.

8. The semiconductor device according to claim 1, wherein the upper portion of the plug has a height, which is equal to a thickness of the stopper insulating film.

9. A method of manufacturing a semiconductor device, comprising:
forming a stopper insulating film on a first interlayer insulating film;
forming a connection hole in the first interlayer insulating film and the stopper insulating film;
forming a plug material film on the stopper insulating film and in the connection hole;
removing that part of the plug material film which is formed on the stopper insulating film using the stopper insulating film as a stopper, thereby forming a plug in the connection hole;
forming a mask portion on the stopper insulating film and the plug;
etching the stopper insulating film using the mask portion as a mask, thereby exposing an upper surface of the first interlayer insulating film;
forming a second interlayer insulating film surrounding the mask portion on the first interlayer insulating film;
removing the mask portion to form a trench for wiring; and
forming a wire connected to the plug in the trench.

10. The method according to claim 9, wherein the mask portion is selectively etched relative to the stopper insulating film, the plug and the second interlayer insulating film, in removing the mask portion.

11. The method according to claim 9, wherein the stopper insulating film is selectively etched relative to the plug and the first interlayer insulating film, in etching the stopper insulating film.

12. The method according to claim 9, wherein an upper surface of the plug formed in the connection hole is flush with an upper surface of the stopper insulating film.

13. The method according to claim 9, wherein the second interlayer insulating film has a dielectric constant, which is lower than that of the stopper insulating film.

14. The method according to claim 9, wherein the stopper insulating film is used as a CMP stopper.
